(19) United States
(12) Patent Application Publication
(10) Pub. No.: US 2026/0068158 A1
(43) Pub. Date: Mar. 5, 2026

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventors: Hwae Bong JUNG, Icheon-si Gyeonggi-do (KR); Jae Seok KIM, Icheon-si Gyeonggi-do (KR)

(73) Assignee: SK hynix Inc., Icheon-si Gyeonggi-do (KR)

(21) Appl. No.: 19/002,086

(22) Filed: Dec. 26, 2024

(30) Foreign Application Priority Data
Sep. 5, 2024 (KR) 10-2024-0120890

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device includes: a gate structure including conductive layers and insulating layers that are alternately stacked; channel structures extending through a cell region of the gate structure; contact plugs located in a contact region of the gate structure and respectively connected to the conductive layers; a slit structure extending from the cell region to the contact region; a first support located in the contact region and in contact with one sidewall of the slit structure; and a second support located in the contact region and in contact with the other sidewall of the slit structure.

### CROSS-REFERENCE TO RELATED APPLICATION

The present application claims priority under 35 U.S.C. § 119(a) to Korean Patent Application No. 10-2024-0120890 filed in the Korean Intellectual Property Office on Sep. 5, 2024, which application is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a gate structure including conductive layers and insulating layers that are alternately stacked; channel structures extending through a cell region of the gate structure; contact plugs located in a contact region of the gate structure and respectively connected to the conductive layers; a slit structure extending from the cell region to the contact region; a first support located in the contact region and in contact with one sidewall of the slit structure; and a second support located in the contact region and in contact with the other sidewall of the slit structure.

In an embodiment, a manufacturing method of a semiconductor device may include: forming a stack including first material layers and second material layers that are alternately stacked; forming a support in the stack, the support including a void; removing the void by forming a slit intersecting the support; replacing the first material layers with third material layers through the slit; and forming a slit structure in the slit.

In an embodiment, a manufacturing method of a semiconductor device may include: forming a stack over a source sacrificial layer, the stack including first material layers and second material layers that are alternately stacked; forming a channel structure extending into the source sacrificial layer through the stack; forming a support in the stack, the support including a void; removing the void by forming a slit intersecting the support; replacing the source sacrificial layer with a source layer through the slit; and forming a slit structure in the slit.

### BRIEF DESCRIPTION OF THE DRAWINGS

FIGS. 1A and 1B are diagrams illustrating the structure of a semiconductor device in accordance with an embodiment.

FIG. 2 is a diagram illustrating the structure of a semiconductor device in accordance with an embodiment.

FIGS. 3A to 3D are diagrams illustrating the structure of a semiconductor device in accordance with an embodiment.

FIGS. 4A, 5A, and 6A and FIGS. 4B, 5B, and 6B are diagrams for describing a manufacturing method of a semiconductor device in accordance with an embodiment.

FIGS. 7A, 8A, 9A, 10A, and 11A and FIGS. 7B, 8B, 9B, 10B, and 11B are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, for some embodiments, it is possible to improve the degree of integration of a semiconductor device. For some embodiments, it is also possible to provide a semiconductor device having a stable structure and improved reliability.

Hereafter, embodiments in accordance with the technical spirit of the present disclosure will be described with reference to the accompanying drawings. Terms such as “first” and “second” are used to distinguish between various elements and do not imply size, order, priority, quantity, or importance of the elements. For example, a first element may be named as a second element in one example, and the second element may be named as a first element in another example. Terms such as “below,” “vertical,” “horizontal,” “over,” “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials for the areas. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

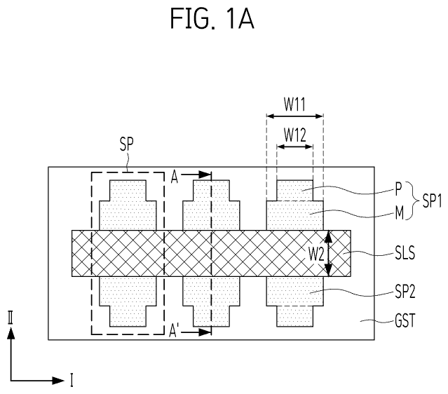

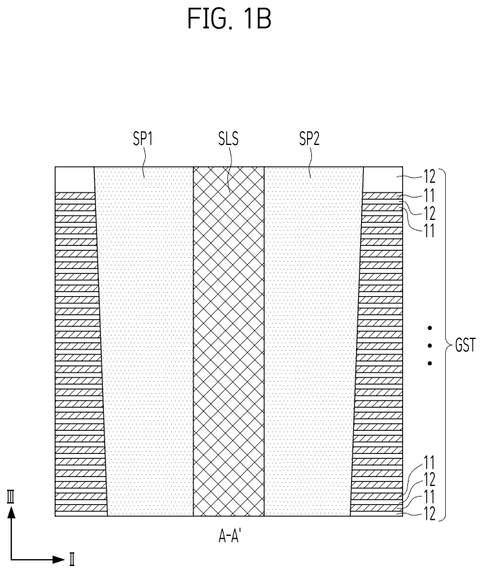

FIGS. 1A and 1B are diagrams illustrating the structure of a semiconductor device in accordance with an embodiment. FIG. 1B is a cross-sectional view taken along line A-A′ of FIG. 1A.

Referring to FIGS. 1A and 1B, the semiconductor device may include a gate structure GST, a slit structure SLS, a first support SP1, and a second support SP2. The gate structure GST may include conductive layers 11 and insulating layers 12 that are alternately stacked. The conductive layers 11 may be gate lines such as a source select line, a drain select line, and word lines. The conductive layers 11 may each include a conductive material such as polysilicon, tungsten, or molybdenum. The insulating layers 12 may be used to insulate the stacked conductive layers 11 from each other. The insulating layers 12 may each include an insulating material such as oxide, nitride, or an air gap.

The slit structure SLS may extend through the gate structure GST. In a plane defined by a first direction I and a second direction II intersecting the first direction I, the slit structure SLS may extend in the first direction I. In a cross section defined by the second direction II and a third direction III, the slit structure SLS may extend in the third direction III. Here, the third direction III may be a stacking direction, and may be a direction perpendicular to the plane defined by the first direction I and the second direction II. The slit structure SLS may include an insulating material, a semiconductor material, or a conductive material or include a combination thereof.

The first support SP1 may be in contact with one sidewall of the slit structure SLS, and the second support SP2 may be in contact with the other sidewall of the slit structure SLS. A pair of first support SP1 and second support SP2 may be adjacent to each other in the second direction II. The pair of first support SP1 and second support SP2 may be formed by separating one support SP by the slit structure SLS. The slit structure SLS may intersect the support SP, and the support SP may be separated into the first support SP1 and the second support SP2 by the slit structure SLS. The slit structure SLS may have a line shape with a second width W2. In an embodiment, the second width W2 may be determined so that an intersection region between the slit structure SLS and the support SP may have a sufficient area.

The pair of first support SP1 and second support SP2 may have a symmetrical shape based on the slit structure SLS. The first support SP1 may include a main portion M and a protrusion portion P. The main portion M may be in contact with the slit structure SLS, and the protrusion portion P may protrude from the main portion M in the second direction II. The main portion M may have a first width W11 in the first direction I, and the protrusion portion P may have a second width W12 in the first direction I. The second width W12 may be smaller than the first width W11.

For reference, a case where the slit structure SLS and the support SP intersect each other at the center of the support SP has been described in FIGS. 1A and 1B, but this is only an example, and the present disclosure is not limited thereto. The support SP may have different widths depending on regions, and a portion of the support SP having a relatively great width may intersect the slit structure SLS. The slit structure SLS and the support SP may intersect each other at a portion biased to one side of the support SP, and in such a case, the first support SP1 and the second support SP2 may have an asymmetrical shape.

According to the structure described above, the supports SP1 and SP2 and the slit structure SLS may be in contact with each other, and the conductive layers 11 and the insulating layers 12 might not exist between the supports SP1 and SP2 and the slit structure SLS. Because the supports SP1 and SP2 and the slit structure SLS are in contact with each other, a space for forming a structure such as a contact plug may be secured.

In an embodiment, the first support SP1 and the second support SP2 may each have a void-free structure in which they do not include a void therein. In an embodiment, the void formed in the support SP in a manufacturing process may be removed in a process of forming the slit structure SLS, and an issue such as a bridge caused by the void may be improved.

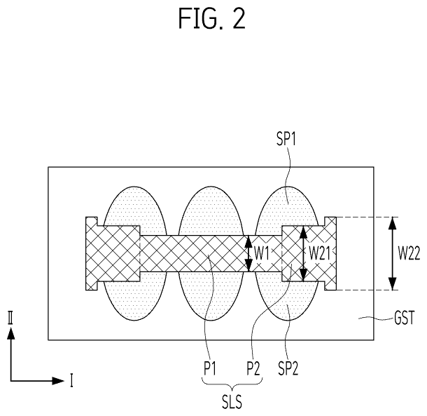

FIG. 2 is a diagram illustrating the structure of a semiconductor device in accordance with an embodiment. Hereinafter, the content overlapping with the previously described content may be omitted.

Referring to FIG. 2, the semiconductor device may include a gate structure GST, a slit structure SLS, a first support SP1, and a second support SP2. The slit structure SLS may extend in the first direction I through the gate structure GST. The first support SP1 may be in contact with one sidewall of the slit structure SLS, and the second support SP2 may be in contact with the other sidewall of the slit structure SLS.

The slit structure SLS may include a first portion P1 and a second portion P2. The first portion P1 may correspond to a central portion, and the second portion P2 may correspond to an end portion. The second portion P2 may be in contact with the first support SP1 and the second support SP2. The first portion P1 may have a first width W1, and the second portion P2 may have second widths W21 and W22 greater than the first width W1. In a plan view, the second portion P2 may have a shape in which a width thereof increases in a staircase shape, and the second width W22 may be greater than the second width W21.

According to the structure described above, the slit structure SLS may have a shape in which an end portion thereof is expanded. Through this, in an embodiment, even at the end portion of the slit structure SLS, an overlap area between the support and the slit structure SLS may be sufficiently secured, and a void in the support in contact with the second portion P2 of the slit structure SLS may be removed in a manufacturing process.

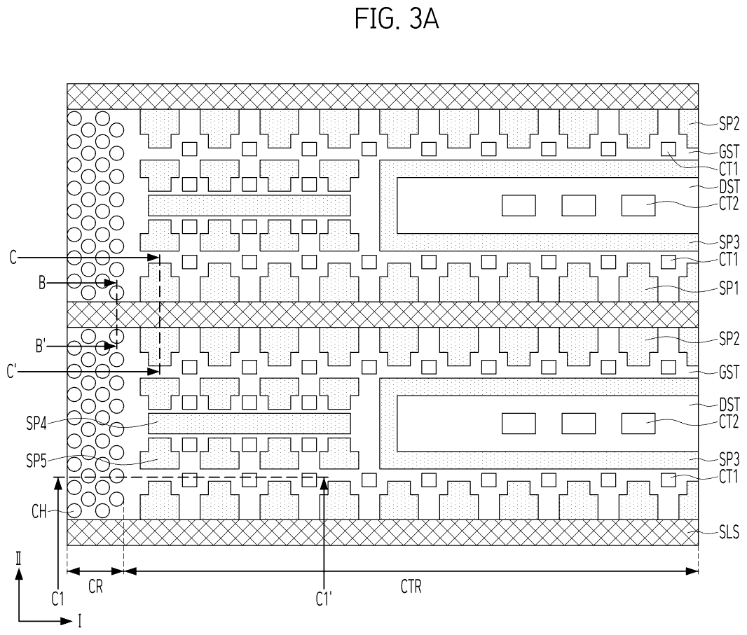

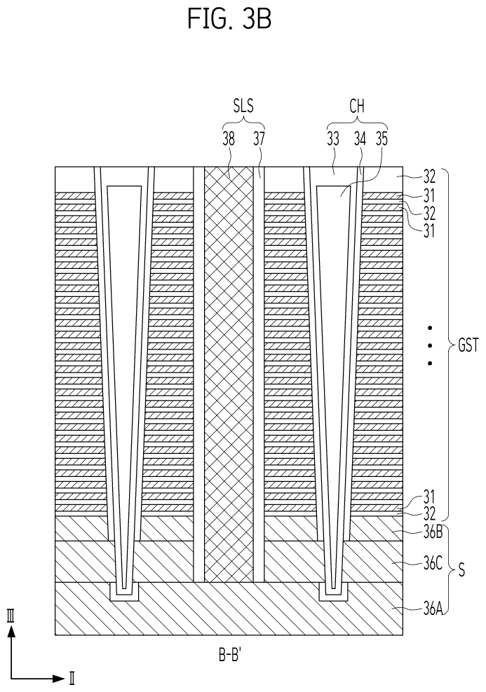

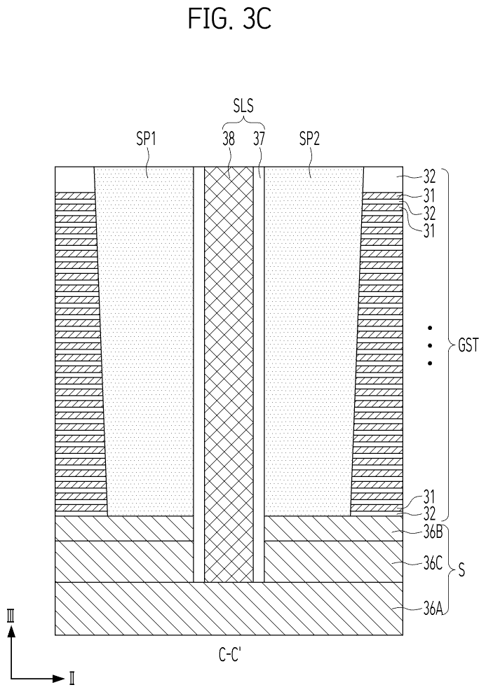

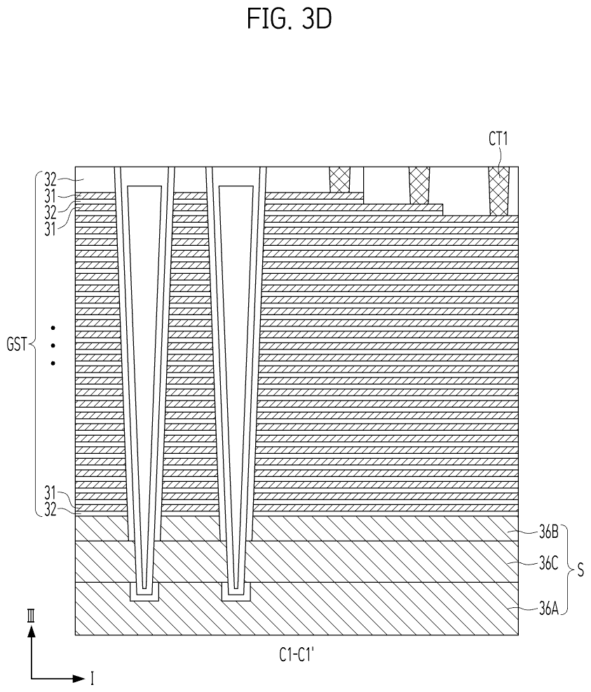

FIGS. 3A to 3D are diagrams illustrating the structure of a semiconductor device in accordance with an embodiment. Hereinafter, the content overlapping with the previously described content may be omitted.

Referring to FIGS. 3A to 3D, the semiconductor device may include a gate structure GST, channel structures CH, first contact plugs CT1, a slit structure SLS, a first support SP1, and a second support SP2. The semiconductor device may further include a source structure S, second contact plugs CT2, a third support SP3, and a fourth support SP4.

The source structure S may have a single-layer or multilayer structure. As an example, the source structure S may include a first source layer 36A, a second source layer 36B, and a third source layer 36C located between the first source layer 36A and the second source layer 36B. The source structure S may include a conductive material such as polysilicon, tungsten, or molybdenum.

The gate structure GST may be located over the source structure S, and may include conductive layers 31 and insulating layers 32 that are alternately stacked. The gate structure GST may include a cell region CR and a contact region CTR. The cell region CR may be a region where stacked memory cells are located. The contact region CTR may be a region where an interconnection structure such a contact plug and a wiring line are located. The cell region CR and the contact region CTR may be adjacent to each other in the first direction I.

The slit structure SLS may extend from the cell region CR to the contact region CTR. In a plan view, the slit structure SLS may extend in the first direction I. In a cross section, the slit structure SLS may extend through the gate structure GST, and may be connected to the source structure S.

The slit structure SLS may include a source contact 38 and an insulating spacer 37. The source contact 38 may extend through the gate structure GST, and may be electrically connected to the source structure S. The source contact 38 may include a conductive material such as polysilicon or tungsten. The insulating spacer 37 may surround sidewalls of the source contact 38. The insulating spacer 37 may include an insulating material such as oxide or nitride.

The channel structures CH may extend through the cell region CR of the gate structure GST, and may extend into the source structure S. In a plan view, the channel structures CH may be arranged in the first direction I and the second direction II. In a cross section, the channel structures CH may extend in the third direction III. In an embodiment, the source structure S may be located below the gate structure GST and may be connected to the channel structures CH. In an embodiment, the source structure S may be connected to the channel structures CH and the gate structure GST may be located over the source structure S.

Each of the channel structures CH may include a channel layer 33, a memory layer 34 surrounding the channel layer 33, and an insulating core 35 located in the channel layer 33. The memory layer 34 may include at least one of a tunneling layer, a data storage layer, and a blocking layer. The data storage layer may include a floating gate, polysilicon, a charge trap material, nitride, a variable resistance material, or the like. The channel structures CH may be connected to the source structure S. The channel layer 33 may be directly connected to the source structure S or indirectly connected to the source structure S through an epitaxial layer.

The first support SP1 may extend through the contact region CTR of the gate structure GST. In a cross section, the first support SP1 may extend in the third direction III. In a plan view, the first supports SP1 may be arranged along one sidewall of the slit structure SLS.

The second support SP2 may extend through the contact region CTR of the gate structure GST. In a cross section, the second support SP2 may extend in the third direction III. In a plan view, the second supports SP2 may be arranged along the other sidewall of the slit structure SLS.

The first support SP1 and the second support SP2 may be adjacent to each other in the second direction II with the slit structure SLS interposed therebetween. The slit structure SLS may extend between a pair of first support SP1 and second support SP2 adjacent to each other in the second direction II. The first support SP1 and the second support SP2 may have a symmetrical shape based on the slit structure SLS. End portions of the first support SP1 and the second support SP2 spaced apart from the slit structure SLS may each have a relatively small width. For example, the first support SP1 may have a first edge contacting the slit structure and a second edge spaced apart from the slit structure SLS, and a width of the second edge is small than a width of the first edge. The end portions of the first support SP1 and the second support SP2 may include protrusion portions, and the protrusion portions may protrude between the first contact plugs CT1.

The third support SP3 may be used to define a dummy stack DST inside the gate structure GST. In a plan view, a portion of the gate structure GST may be surrounded by the third support SP3, and a region surrounded by the third support SP3 may be defined as the dummy stack DST. The dummy stack DST may include dielectric layers and insulating layers 32 that are alternately stacked. The dielectric layers may be located at the same levels as the conductive layers 31, and may be sacrificial layers remaining in a manufacturing process.

The fourth support SP4 may extend through the contact region CTR of the gate structure GST. In a cross section, the fourth support SP4 may extend in the third direction III. In a plan view, the fourth support SP4 may have a line shape in which it extends in the first direction I. The fourth support SP4 may be located between the channel structures CH and the third support SP3.

A fifth support SP5 may extend through the contact region CTR of the gate structure GST. In a cross section, the fifth support SP5 may extend in the third direction III. In a plan view, the fifth support SP5 may have a T shape. The fifth support SP5 may be located between the first supports SP1 and the fourth support SP4 or between the second supports SP2 and the fourth support SP4.

The first contact plugs CT1 may be located in the contact region CTR, and may be respectively connected to the conductive layers 31. As an example, the contact region CTR of the gate structure GST may have a staircase shape, and the first contact plugs CT1 may be respectively connected to pads defined in a staircase shape. As an example, the contact region CTR of the gate structure GST may have a flat upper surface, and the first contact plugs CT1 may extend to the inside of the gate structure GST and be respectively connected to the conductive layers 31. The first contact plugs CT1 may be located between the first supports SP1, between the second supports SP2, or between the fifth supports SP5.

The second contact plugs CT2 may extend through the dummy stack DST, and may extend in the third direction III. As an example, a peripheral circuit may be located below the source structure S, and the second contact plugs CT2 may penetrate through the dummy stack DST and be electrically connected to the peripheral circuit.

According to the structure described above, the first support SP1 and the second support SP2 may be in contact with the slit structure SLS. In an embodiment, because there is no need to consider distances between the first and second supports SP1 and SP2 and the slit structure SLS, a space in which the first contact plugs CT1 are to be formed may be secured. In addition, in an embodiment, the first support SP1 and the second support SP2 may each have a void-free structure. Accordingly, in an embodiment, the semiconductor device may have a stable structure.

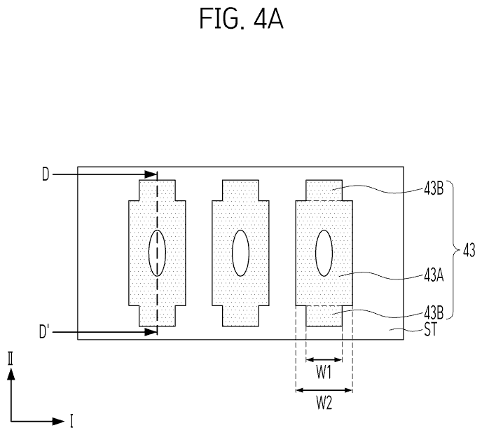

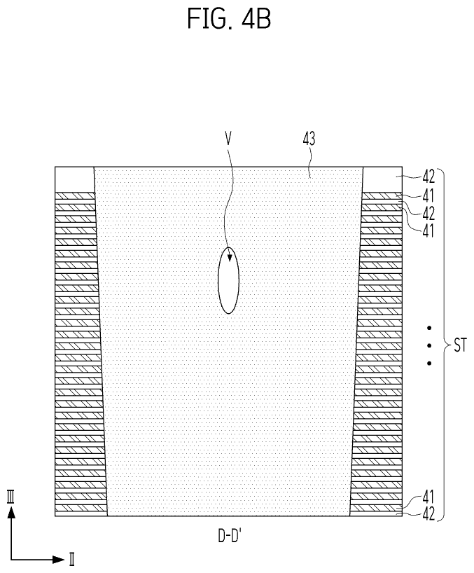

FIGS. 4A, 5A, and 6A and FIGS. 4B, 5B, and 6B are diagrams for describing a manufacturing method of a semiconductor device in accordance with an embodiment. Hereinafter, the content overlapping with the previously described content may be omitted.

Referring to FIGS. 4A and 4B, a stack ST including first material layers 41 and second material layers 42 that are alternately stacked may be formed. The first material layers 41 may each include a material having a high etching selectivity with respect to the second material layers 42. The first material layers 41 may be used to form gate lines. The first material layers 41 may each include a sacrificial material such as nitride or a conductive material such as polysilicon or metal. The second material layers 42 may be used to insulate the stacked gate lines from each other. The second material layers 42 may each include an insulating material such as oxide, nitride, or an air gap.

Subsequently, a support 43 including a void V may be formed in the stack ST. As an example, a trench may be formed in the stack ST, and the support 43 may be formed by depositing an insulating material in the trench. In a process of depositing the insulating material, an empty space that is not filled with the insulating material may be generated in the trench, and such an empty space may be defined as the void V.

In a plan view, the support 43 may extend in the second direction II, and may include a central portion 43A and end portions 43B. The central portion 43A may be located between the end portions 43B. In the first direction I, the end portion 43B may have a first width W1, and the central portion 43A may have a second width W2 greater than the first width W1 of the end portion 43B. The void V may be formed in a portion of the support 43 having a relatively greater width. In a plan view, the central portion 43A may have greater width than the end portion, and the void V may be located in the central portion 43A. In a cross section, the support 43 may have a smaller width in a lower surface thereof than in an upper surface thereof. The void V may be located at an upper portion of the support 43.

For reference, a plurality of supports 43 may be formed in the stack ST. The supports 43 may be arranged in the first direction I and/or the second direction II. In a plan view, the supports 43 may each have a shape such as a circular shape, an elliptical shape, or a polygonal shape. As an example, the support 43 may have an elliptical shape having a major axis extending in the second direction II and a minor axis extending in the first direction I.

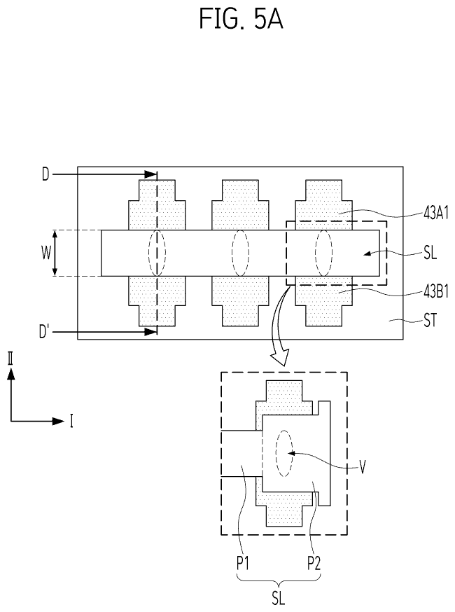

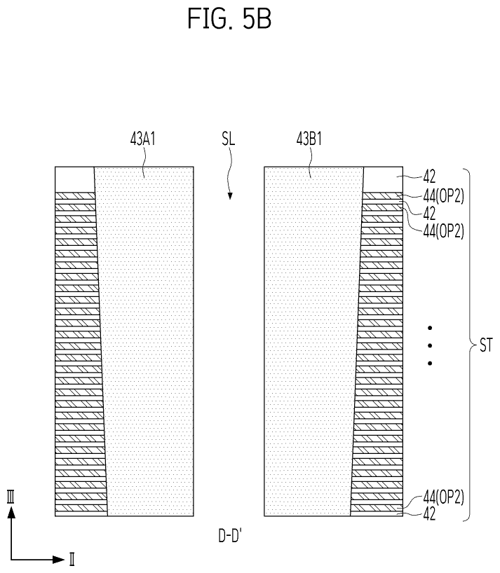

Referring to FIGS. 5A and 5B, a slit SL may be formed in the stack ST. The slit SL may intersect the support 43, and may extend in the first direction I. As an example, the slit SL may be formed by etching the stack ST and the support 43. The slit SL may penetrate through a region of the support 43 where the void V is formed. As an example, the slit SL may penetrate through the central portion 43A of the support 43.

In a process of etching the support 43 in order to form the slit SL, the void V may be removed. The slit SL may have a width W enough to completely remove the void V. As an example, the slit SL and the void V may have substantially the same width or the slit SL may have a greater width than the void V.

During an etching process for forming the slit SL, an end portion of the slit SL may be formed to have a relatively smaller width than a center portion due to a limitation of the etching process. In such a case, the void V in the support 43 overlapping with the end portion of the slit SL might not be completely removed. Accordingly, according to an embodiment of the present disclosure, the slit SL may be formed so that an end portion P2 has a greater width than a central portion P1. The end portion P2 may overlap with the support 43, and may have the same width as the void V or a greater width than the void V. Through this, the void V in the support 43 overlapping with the end portion P2 of the slit SL may also be completely removed.

The support 43 may be separated into a first support 43A1 and a second support 43B1 by the slit SL. Because the void V is removed by the slit SL, the first support 43A1 and the second support 43B1 may each have a void-free structure.

Subsequently, the first material layers 41 may be replaced with third material layers 44 through the slit SL. As an example, second openings OP2 may be formed by removing the first material layers 41 through the slit SL. Subsequently, a conductive layer filling the second openings OP2 and extending into the slit SL may be formed. Subsequently, the third material layers 44 respectively located in the second openings OP2 may be formed by etching the conductive layer. Here, the third material layers 44 may be gate lines such as a source select line, a drain select line, and word lines. Through this, a gate structure GST including the third material layers 44 and the second material layers 42 that are alternately stacked may be formed.

When the void is not completely removed in a process of forming the slit SL, the void and the slit SL may be connected to each other. In such a case, the conductive layer may remain in the void of the first support 43A1 and/or the second support 43B1 or may remain in the slit SL, which may cause a defect such as a bridge. According to an embodiment of the present disclosure, the void V is completely removed in the process of forming the slit SL, and thus, a defect caused by the void V may be improved.

For reference, when the first material layers 41 each include the conductive material, the first material layers 41 might not be removed. As an example, the first material layers 41 may include polysilicon layers, respectively, and the polysilicon layers may be metal-silicided through the slit SL. Alternatively, the first material layers 41 may be used as the third material layers 44, and the stack ST may be used as the gate structure GST.

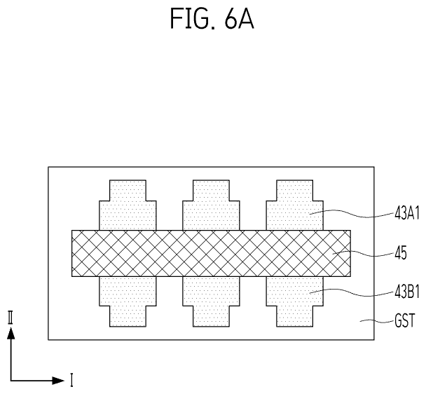

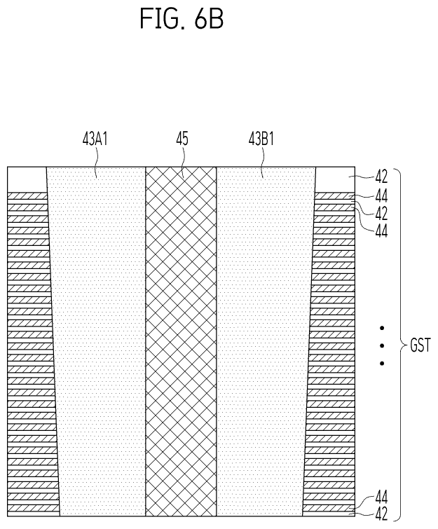

Referring to FIGS. 6A and 6B, a slit structure 45 may be formed in the slit SL. As an example, the slit structure 45 may include an insulating material, a semiconductor material, or a conductive material or include a combination thereof.

According to the manufacturing method described above, the void V may be removed through the slit SL, which is a passage for replacing the first material layers 41 with the third material layers 44. Accordingly, the void V in the support 43 may be removed without adding a separate process. In addition, in an embodiment, by removing the void V in the support 43, it is possible to reduce the occurrence of a defect due to the remaining conductive material.

The slit SL may be formed to overlap with the support 43, and the first and second supports 43A1 and 43A2 may be in contact with the slit structure 45. Accordingly, in an embodiment, the stack ST might not exist between the first and second supports 43A1 and 43B1, and the occurrence of a defect such as a bridge due to the remaining stack ST may be prevented or mitigated.

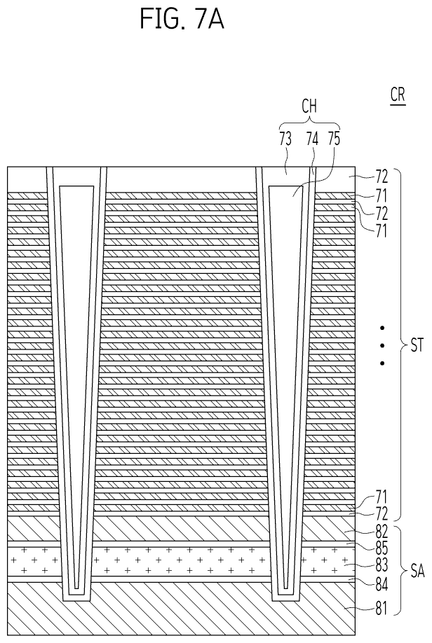

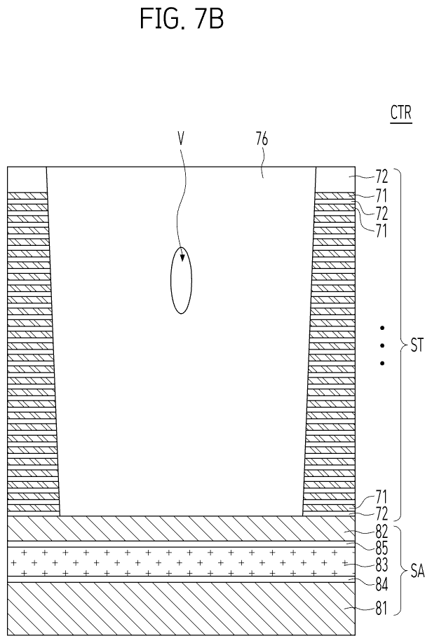

FIGS. 7A, 8A, 9A, 10A, and 11A and FIGS. 7B, 8B, 9B, 10B, and 11B are diagrams for describing a manufacturing method of a semiconductor device in accordance with an embodiment. FIGS. 7A, 8A, 9A, 10A, and 11A are cross-sectional views of cell regions, and FIGS. 7B, 8B, 9B, 10B, and 11B are cross-sectional views of contact regions. Hereinafter, the content overlapping with the previously described content may be omitted.

Referring to FIGS. 7A and 7B, a source structure SA including a source sacrificial layer 83 may be formed. The source structure SA may further include a first source layer 81 and a second source layer 82, and the source sacrificial layer 83 may be located between the first source layer 81 and the second source layer 82. The source structure SA may further include a first protective layer 84 located between the first source layer 81 and the source sacrificial layer 83 and a second protective layer 85 located between the second source layer 82 and the source sacrificial layer 83. The source sacrificial layer 83 may include a material having a high etching selectivity with respect to the first protective layer 84 and the second protective layer 85. As an example, the first protective layer 84 and the second protective layer 85 may each include oxide, and the source sacrificial layer 83 may include polysilicon.

Subsequently, a stack ST including first material layers 71 and second material layers 72 that are alternately stacked may be formed over the source structure SA. The first material layers 71 may each include a sacrificial material such as nitride or a conductive material such as polysilicon or metal. The second material layers 72 may each include an insulating material such as oxide, nitride, or an air gap. The stack ST may include a cell region CR and a contact region CTR.

Subsequently, a channel structure CH may be formed in the stack ST. The channel structure CH may be located in the cell region CR, and may extend into the source structure SA through the stack ST. As an example, the channel structure CH may extend into the source sacrificial layer 83. The channel structure CH may include a channel layer 73, a memory layer 74 surrounding the channel layer 73, and an insulating core 75 located in the channel layer 73.

Subsequently, a support 76 including a void V may be formed in the stack ST. The support 76 may be located in the contact region CTR. The support 76 may include an insulating material such as oxide or nitride.

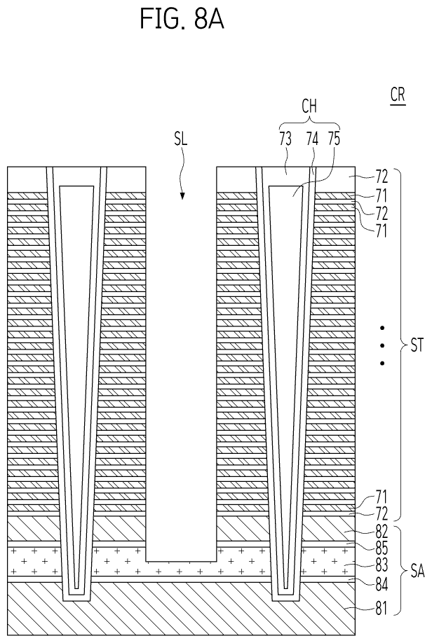

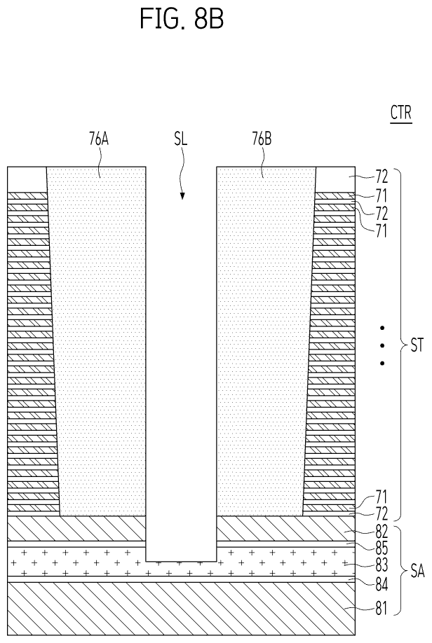

Referring to FIGS. 8A and 8B, a slit SL may be formed in the stack ST. In a cross section, the slit SL may extend into the source structure SA through the stack ST. The source sacrificial layer 83 may be exposed through the slit SL. In a plan view, the slit SL may extend from the cell region CR to the contact region CTR.

The slit SL may intersect the support 76, and may penetrate through a region of the support 76 where the void V is formed. The void V may be removed by the slit SL, and the support 76 may be separated into a first support 76A and a second support 76B. The slit SL may be formed to have a width enough to remove the void V, and the first support 76A and the second support 76B may each have a void-free structure.

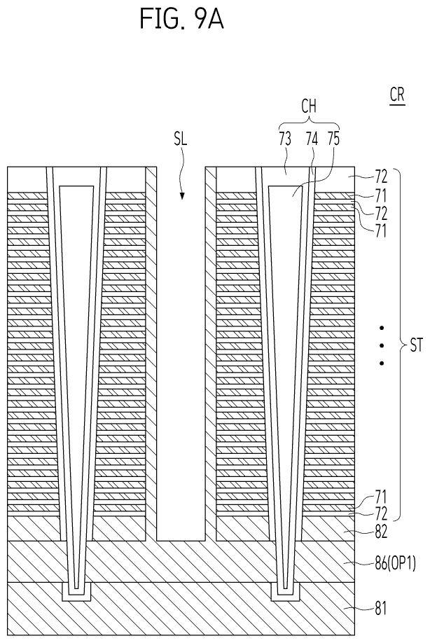

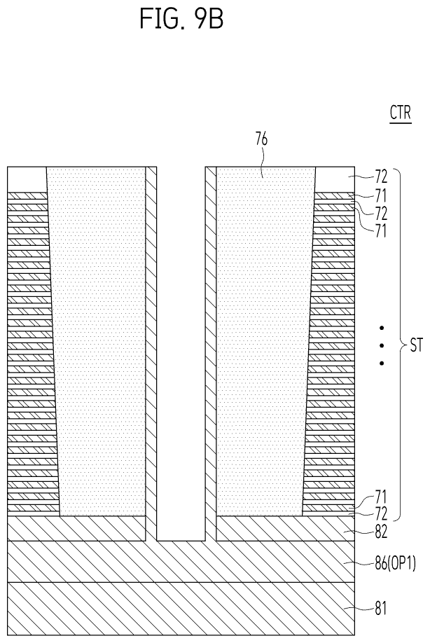

Referring to FIGS. 9A and 9B, a first opening OP1 may be formed by removing the source sacrificial layer 83 through the slit SL. Subsequently, the channel layer 73 may be exposed by removing the memory layer 74 exposed through the first opening OP1. In a process of removing the memory layer 74, the first protective layer 84 and the second protective layer 85 may be removed.

Subsequently, a conductive layer 86 filling the first opening OP1 and extending into the slit SL may be formed. The conductive layer 86 is used to form a third source layer, and may include a conductive material such as polysilicon or metal.

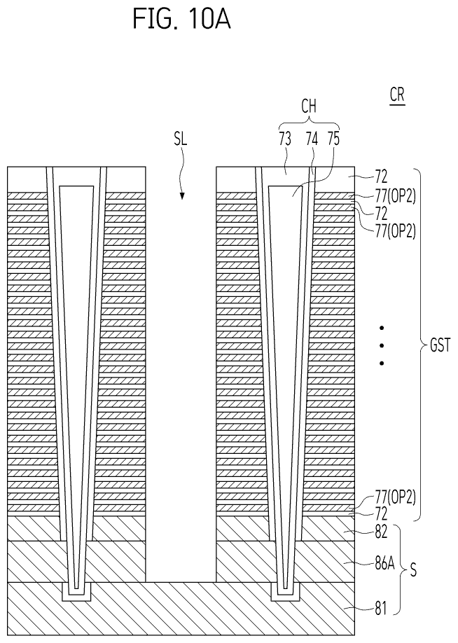

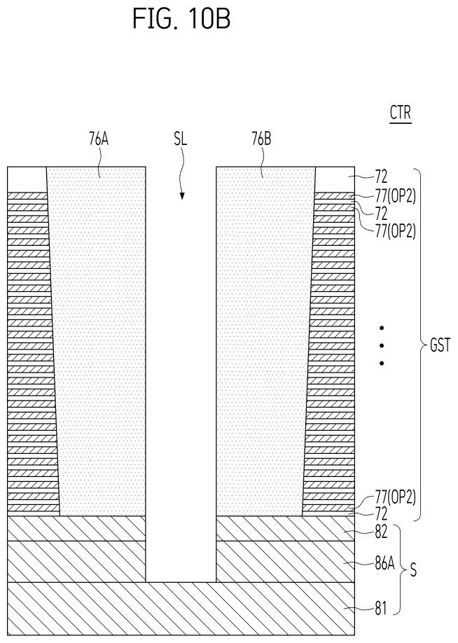

Referring to FIGS. 10A and 10B, a third source layer 86A located in the first opening OP1 may be formed by etching the conductive layer 86. A portion of the conductive layer 86 formed in the slit SL may be etched, and the conductive layer 86 remaining in the first opening OP1 may be defined as the third source layer 86A. Through this, the source sacrificial layer 83 may be replaced with the third source layer 86A, and a source structure S including the first source layer 81, the second source layer 82, and the third source layer 86A may be formed.

In an embodiment, when the void V is not completely removed in a process of forming the slit SL and remains in the first support 76A and the second support 76B, the conductive layer 86 may be deposited in the void V, and a defect may be caused by the remaining conductive material. According to an embodiment of the present disclosure, the void V is completely removed in the process of forming the slit SL, and thus, a defect caused by the void V may be improved.

Subsequently, the first material layers 71 may be replaced with third material layers 77 through the slit SL. As an example, second openings OP2 may be formed by removing the first material layers 71 through the slit SL. A conductive layer filling the second openings OP2 and extending into the slit SL may be formed. The conductive layer may be etched to form the third material layers located in the second openings OP2, respectively. In an embodiment, because the first and second supports 76A and 76B each have the void-free structure, it is possible to prevent or mitigate a conductive material from remaining in the void V or the slit SL in a process of forming the third material layers 77 by depositing and etching a conductive layer.

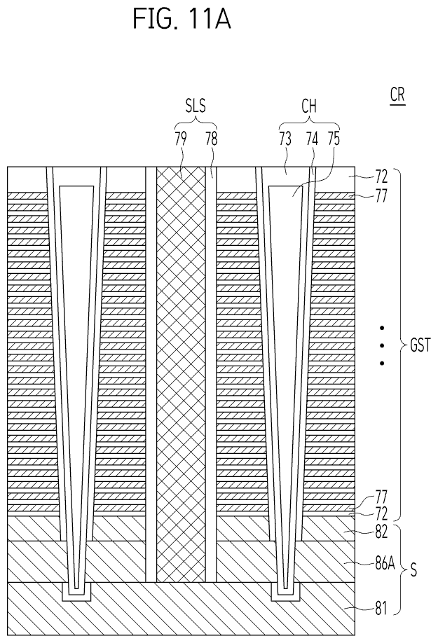

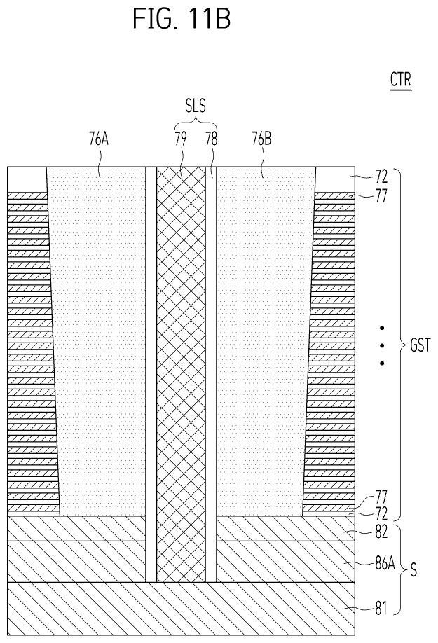

Referring to FIGS. 11A and 11B, a slit structure SLS may be formed in the slit SL. As an example, an insulating spacer 78 may be formed on inner walls of the slit SL, and a conductive layer 79 may be formed in the insulating spacer 78. The conductive layer 79 may be a source contact electrically connected to the source structure S. The insulating spacer 78 may include an insulating material such as oxide or nitride, and the conductive layer 79 may include a conductive material such as polysilicon or metal.

According to the manufacturing method described above, the void V may be removed through the slit SL, which is a passage for replacing the source sacrificial layer 83 with the third source layer 86A. Accordingly, the void V in the support 76 may be removed without adding a separate process. In addition, in an embodiment, by removing the void V in the support 76, it is possible to reduce the occurrence of a defect due to the remaining conductive material.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a gate structure including conductive layers and insulating layers that are alternately stacked;
channel structures extending through a cell region of the gate structure;
contact plugs located in a contact region of the gate structure and respectively connected to the conductive layers;
a slit structure extending from the cell region to the contact region;
a first support located in the contact region and in contact with one sidewall of the slit structure; and
a second support located in the contact region and in contact with the other sidewall of the slit structure.

2. The semiconductor device of claim 1, further comprising a source structure connected to the channel structures,
wherein the gate structure is located over the source structure.

3. The semiconductor device of claim 2, wherein the slit structure comprises:
a source contact extending through the gate structure and electrically connected to the source structure; and
an insulating spacer surrounding sidewalls of the source contact.

4. The semiconductor device of claim 1, wherein the slit structure extends in a first direction, and the first support and the second support are adjacent to each other in a second direction intersecting the first direction.

5. The semiconductor device of claim 1, wherein the first support and the second support have substantially a symmetrical shape based on a location of the slit structure.

6. The semiconductor device of claim 1, wherein the first support is located between the contact plugs.

7. The semiconductor device of claim 6, wherein the first support includes a protrusion portion protruding between the contact plugs.

8. The semiconductor device of claim 1, wherein the first support is spaced apart from the second support by the slit structure.

9. A manufacturing method of a semiconductor device, the manufacturing method comprising:
forming a stack including first material layers and second material layers that are alternately stacked;
forming a support in the stack, the support including a void;
removing the void by forming a slit intersecting the support;
replacing the first material layers with third material layers through the slit; and
forming a slit structure in the slit.

10. The manufacturing method of claim 9, wherein the slit extends in a first direction, and the support extends in a second direction intersecting the first direction.

11. The manufacturing method of claim 10, wherein the support includes a major axis extending in the second direction and a minor axis extending in the first direction.

12. The manufacturing method of claim 10, wherein the support has a greater width at a central portion of the support than an end portion of the support.

13. The manufacturing method of claim 12, wherein the void is located at the central portion, and the slit penetrates through the central portion of the support.

14. The manufacturing method of claim 9, wherein the support is separated into a first support and a second support by the slit.

15. The manufacturing method of claim 14, wherein the first support and the second support each have a void-free structure.

16. The manufacturing method of claim 9, wherein in the removing of the void, the slit is formed to have a width that is substantially the same as or greater than that of the void.

17. The manufacturing method of claim 9, further comprising:
forming a source sacrificial layer;
forming a channel structure extending into the source sacrificial layer through the stack;
forming a first opening by removing the source sacrificial layer through the slit;
forming a third source layer in the first opening.

18. The manufacturing method of claim 17, wherein the forming of the source layer comprises:
forming a conductive layer filling the first opening and extending into the slit; and
forming the third source layer by etching the conductive layer, the third source layer being located in the first opening.

19. The manufacturing method of claim 9, wherein the replacing of the first material layers with the third material layers comprises:
forming second openings by removing the first material layers;
forming a conductive layer filling the second openings and extending into the slit; and
forming the third material layers by etching the conductive layer, the third material layers being respectively located in the second openings.

20. The manufacturing method of claim 9, wherein the forming of the slit structure comprises:
forming an insulating spacer in the slit; and
forming a conductive layer in the insulating spacer.

21. A manufacturing method of a semiconductor device, the manufacturing method comprising:
forming a stack over a source sacrificial layer, the stack including first material layers and second material layers that are alternately stacked;
forming a channel structure extending into the source sacrificial layer through the stack;
forming a support in the stack, the support including a void;
removing the void by forming a slit intersecting the support;
replacing the source sacrificial layer with a source layer through the slit; and
forming a slit structure in the slit.

22. The manufacturing method of claim 21, wherein the slit extends in a first direction, and the support extends in a second direction intersecting the first direction.

23. The manufacturing method of claim 21, wherein the support has a greater width at a central portion of the support than an end portion of the support.

24. The manufacturing method of claim 23, wherein the void is located at the central portion, and the slit penetrates through the central portion of the support.

25. The manufacturing method of claim 21, wherein the support is separated into a first support and a second support by the slit.

26. The manufacturing method of claim 25, wherein the first support and the second support each have a void-free structure.

27. The manufacturing method of claim 21, wherein in the removing of the void, the slit is formed to have a width that is substantially the same as or greater than that of the void.

28. The manufacturing method of claim 21, wherein the replacing of the source sacrificial layer with the source layer comprises:
forming a first opening by removing the source sacrificial layer through the slit;
forming a conductive layer filling the first opening and extending into the slit; and
forming the source layer by etching the conductive layer, the source layer being located in the first opening.

29. The manufacturing method of claim 21, wherein the forming of the slit structure comprises:
forming an insulating spacer in the slit; and
forming a conductive layer in the insulating spacer.
